(19) United States
(12) Patent Application Publication
(10) Pub. No.: US 2012/0007178 A1
(43) Pub. Date: Jan. 12, 2012

(54) SEMICONDUCTOR DEVICE AND MANUFACTURING METHOD THEREOF

(75) Inventor: Tomonari Oota, Osaka (JP)

(73) Assignee: Panasonic Corporation, Osaka (JP)

(21) Appl. No.: 13/256,383

(22) PCT Filed: Feb. 9, 2010
(86) PCT No.: PCT/JP2010/000762

§ 371 Date: Sep. 13, 2011

(51) Int. Cl. H01L 27/088; H01L 21/8234

(52) U.S. Cl. 257/334; 438/270; 257/E27.06; 257/E21.629

(57) ABSTRACT

A semiconductor device having trench gates in element regions R1 formed in a semiconductor substrate. Second trenches T2 having the same depth as that of first trenches T1 making up the trench gates are provided along a marginal area of the semiconductor substrate.

### TECHNICAL FIELD

The present invention relates to a semiconductor device and manufacturing method thereof and, more particularly, to lessening of warpage of a wafer in a semiconductor device, like an insulated gate transistor having a trench structure.

### BACKGROUND ART

With a reduction in power consumption, greater sophistication, and a speedup of electronic devices, including a portable phone, a growing demand recently exists for a reduction in power consumption and a speedup of a semiconductor device accommodated in the electronic devices. To meet the demand, transistors exhibiting smaller on-resistance are generally required for transistors used in load switches of electronic devices, DC-DC converters, and the like. One proposed method for reducing on-resistance of a transistor is to miniaturize individual devices to thereby increase density of transistors to be placed per unit area. Specifically, a density of transistors in a vertical MOSFET having gate electrodes formed in trenches can be increased by means of: placing the trenches, which make up transistors, in the form of a stripe pattern; miniaturizing a width of each of the trenches; and reducing a pitch between adjacent trenches.

A semiconductor device including a plurality of trenches arranged in a semiconductor chip and MOSFETs fabricated in the respective trenches has been available as an example. In the structure, a gate pad is formed in a portion of a surface of the semiconductor chip. Gate electrodes formed by filling the respective trenches with polycrystalline silicon are connected to the gate pad by means of a gate line routed along a marginal area of the individual semiconductor chip (Patent Document 1).

A method for forming a plurality of element regions within a silicon wafer, fabricating MOSFETs in the respective element regions, and separating the elements along scribe regions defined among the element regions into individual element chips by use of a dicing saw has been used for manufacturing the MOSFETs, such as those mentioned above, as in the case of manufacturing method of ordinary semiconductor devices.

Under the circumstance, the diameter of a wafer is recently on the increase in order to increase the number of semiconductor chips manufactured from one wafer to enhance an element yield and curtail manufacturing cost of the semiconductor chip.

An increase in the diameter of the wafer leads to an increase in the influence of warpage. Difficulty is eventually encountered in aligning a mask when element regions are formed by use of; for instance, photolithography, and when a photoresist is exposed to light. Another problem is that a fracture or cracking occurs during conveyance of a wafer. Moreover, when the wafer is separated into chips after cutting trenches have been formed by the dicing saw and when an adhesive tape affixed to the wafer is extended to cut, stress imposed on the wafer becomes greater, which in turn raises a problem of occurrence of chipping.

These problems lead to a decrease in production yield of a semiconductor device, which in turn incurs an increase in manufacturing cost. Therefore, a problem of warpage of a wafer is now a serious problem.

Accordingly, even in relation to the occasion of manufacture of a semiconductor element having a trench gate structure, there has also been proposed a method for forming trenches in scribe regions of a wafer when gate trenches are formed by means of etching, to thus lessen warpage (Patent Document 2).

### RELATED ART DOCUMENT

### Patent Documents

Patent Document 1: JP-A-2007-48769
Patent Document 2: JP-A-2003-332270

### DISCLOSURE OF THE INVENTION

### Problem that the Invention is to Solve

As mentioned above, in relation to the related-art semiconductor device having stripe-shaped trench gates, there are provided descriptions about lessening warpage by forming trenches in scribe regions provided in a marginal area. As illustrated in connection with Patent Document 2 (FIG. 4 or FIG. 8), deep trenches are formed. Deep trenches are thus formed to such an extent that they reach a lower surface of an epitaxial growth layer.

For this reason, there are also other problems that manufacture of the semiconductor device involves consumption of much time and that an occupied area increases.

The present invention has been conceived in light of the circumstance and aims at providing a highly reliable semiconductor device that is easy to manufacture.

### Means for Solving the Problem

In order to solve the problem, the present invention is directed toward a semiconductor device having trench gates in an element region formed in a semiconductor substrate and characterized in that second trenches having the same depth as that of first trenches making up the trench gates are formed in a marginal area of the semiconductor substrate.

In the configuration, the second trenches formed in respective scribe regions have the same depth as that of the first trenches making up the trench gates. Hence, since the second trenches are shallower than are related-art second trenches, it is possible to maintain mechanical strength well while an effect of preventing occurrence of warpage in a wafer is maintained. Trade-off requirements can be satisfied. Since the second trenches are simultaneously formed in the scribe regions in the step of forming the trench gates, manufacturing cost becomes lower. Trenches are formed over an entire wafer, and hence it becomes possible to make a geometry of trenches stable in the trench etching step. Variations in electrical characteristic are therefore lessened, and yield can be enhanced.

The present invention is directed toward the semiconductor device, wherein a polycrystalline silicon film is formed on interior walls of the respective second trenches by way of an oxide film.

In the configuration, the trenches are formed in the scribe regions without addition of any steps by means of changing only masks used for forming the trench gates; hence, operability is extremely enhanced.

The present invention is directed toward the semiconductor device, wherein the semiconductor substrate is formed from a semiconductor base material and an epitaxial growth layer formed on a surface of the semiconductor base material; and wherein the first trenches and the second trenches have such a depth that they do not reach an interface between the semiconductor base material and the epitaxial growth layer.

In the configuration, the first and second trenches are made shallow. Therefore, yield of the semiconductor devices can be enhanced without involvement of exfoliation of the epitaxial growth layer.

The present invention is directed toward the semiconductor device, wherein the second trenches are formed in parallel to the first trenches.

The configuration makes it possible to perform stable patterning when the trenches are formed by performing etching along a mask pattern.

The present invention is directed toward the semiconductor device, wherein the second trenches are parallel to edges of the respective element regions and formed so as to surround the respective element regions.

In the configuration, the trenches are formed so as to surround the respective element regions, and hence a more stable geometry can be acquired.

The present invention is directed toward the semiconductor device, wherein the second trenches have the same width as that of the first trenches.

In the configuration, patterning is easy, and the entire surface of the substrate is subjected to substantially uniform trench etching. Hence, accuracy of etching is also enhanced.

The present invention is directed toward the semiconductor device and includes the steps of: preparing a semiconductor substrate; forming first trenches in element regions of the semiconductor substrate and second trenches in scribe regions surrounding the respective element regions; oxidizing interior walls of the first and second trenches, to thus produce a silicon oxide film, and filling interiors of the trenches with polycrystalline silicon, to form gate electrodes in the first trenches; forming trench gate semiconductor devices through introduction of impurities and formation of electrodes; and separating the substrate into a plurality of semiconductor devices by bringing a dicing blade into contact with the scribe regions.

In the configuration, trenches can be simultaneously formed also in the scribe regions by means of single trench etching operation, and ease of manufacturing operation becomes extremely enhanced. Further, the second trenches have the same depth as that of the first trenches making up the trench gates, and hence mechanical strength can be maintained well while an effect of preventing occurrence of warpage in a wafer is maintained. Further, the trenches are formed over the entire wafer, so that the shape of the trenches can be made stable in the trench etching step.

The present invention is directed toward the method for manufacturing a semiconductor device, wherein a silicon oxide film is formed on respective interior walls of the first trenches, and the first trenches are filled with polycrystalline silicon, to thus form the gate electrodes; and simultaneously a silicon oxide film is also formed on respective interior walls of the second trenches, and the second trenches are filled with polycrystalline silicon.

The present invention is also directed toward the method for manufacturing a semiconductor device, wherein the step of preparing the semiconductor substrate includes the steps of: forming an epitaxial growth layer on a surface of a semiconductor base material; and forming the first and second trenches to such a depth that they do not reach an interface between the semiconductor base material and the epitaxial growth layer.

The present invention is also directed toward the method for manufacturing a semiconductor device, wherein the step of forming trenches includes the step of simultaneously forming the first and second trenches in such a way that the second trenches become parallel to the first trenches.

The present invention is also directed toward the method for manufacturing a semiconductor device, wherein the step of forming trenches includes a step of simultaneously forming the first and second trenches in such a way that the second trenches become parallel to edges of the element regions so as to surround the respective element regions.

The present invention is also directed toward the method for manufacturing a semiconductor device, wherein the second trenches are formed in numbers at a predetermined pitch within the respective scribe regions so as to have the same width as that of the first trenches.

### Advantage of the Invention

As has been described in detail, in the semiconductor device of the present invention, occurrence of warpage in a wafer is prevented, and accuracy of patterning is enhanced. Therefore, a highly reliable semiconductor device can be provided with high accuracy.

Since forming trenches in the respective scribe regions is realized in the same step of production of trench gates, manufacturing cost can be curtailed.

A geometry of trenches can be made stable, and occurrence of variations in electrical characteristic can be prevented. Reliability of the semiconductor device can be enhanced.

### BRIEF DESCRIPTION OF THE DRAWINGS

FIG. 1 is a cross sectional view of a principal portion of a trench MOSFET of a first embodiment of the present invention.

FIG. 2 is an enlarged cross sectional view of a principal portion of the trench MOSFET of the first embodiment of the present invention.

FIG. 3 is a top view of the trench MOSFET of the first embodiment of the present invention.

FIG. 4 is a cross sectional view taken along line A-A shown in FIG. 3.

FIGS. 5 (a) to (d) are views showing a step for manufacturing the trench MOSFET of the first embodiment of the present invention.

FIG. 6 is an explanatory view of a principal portion of a semiconductor wafer achieved in the step for manufacturing the MOSFET.

FIG. 7 is an explanatory view of a principal portion of a semiconductor wafer achieved in a step for manufacturing a trench MOSFET of a second embodiment of the present invention.

FIG. 8 is an enlarged cross sectional view of a principal portion of a trench MOSFET of a third embodiment of the present invention.

### EMBODIMENTS FOR IMPLEMENTING THE INVENTION

Embodiments of the present invention are hereunder described in detail by reference to the drawings.

### First Embodiment

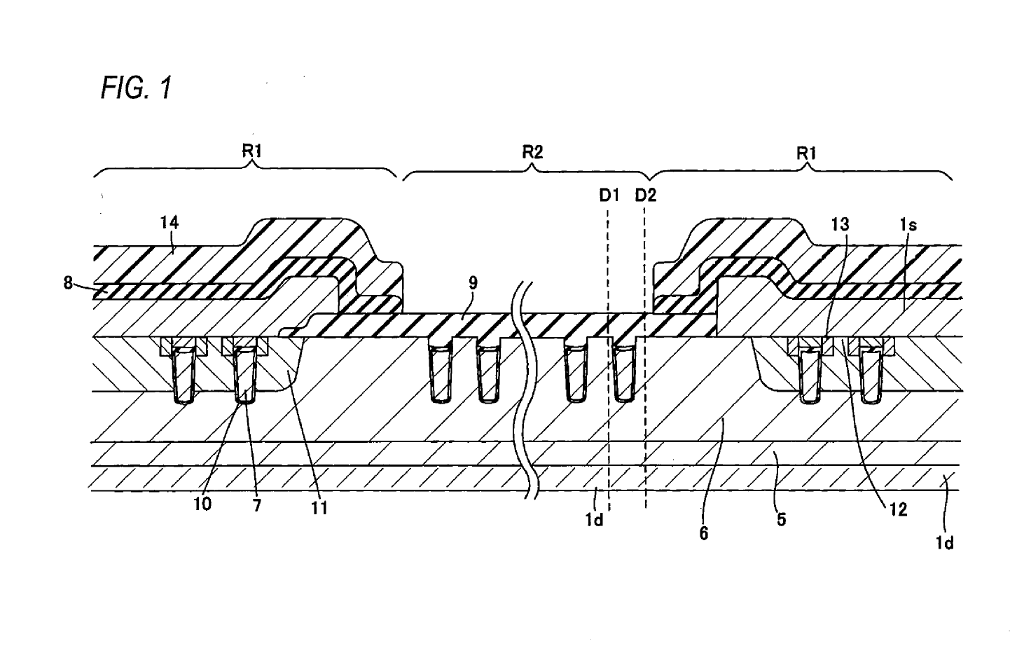

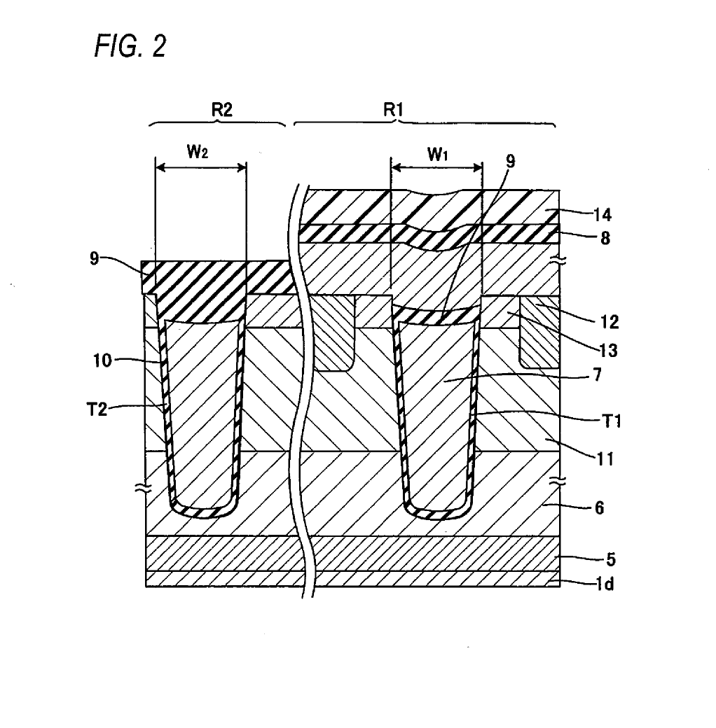

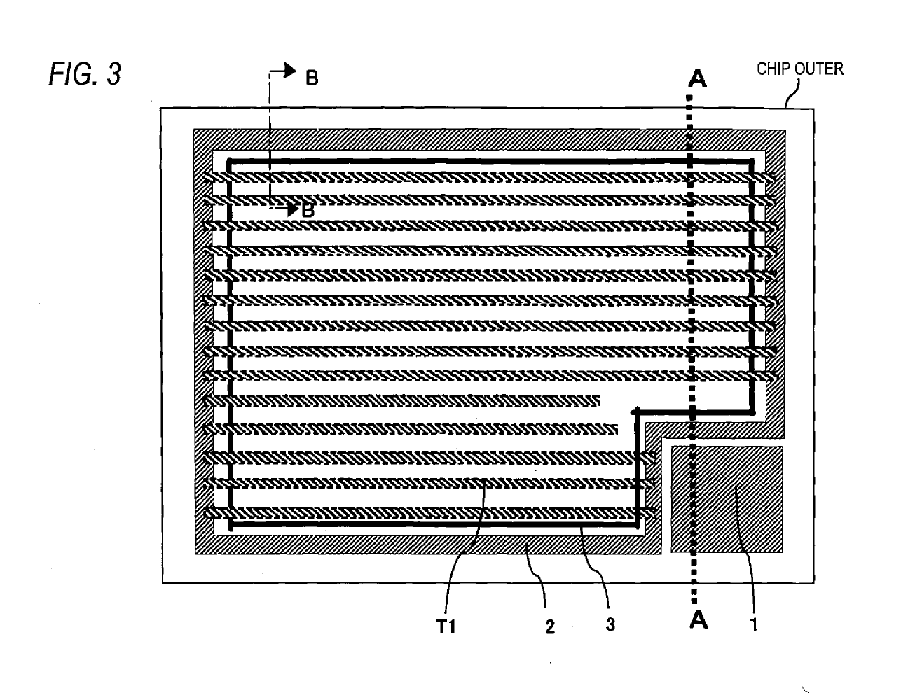

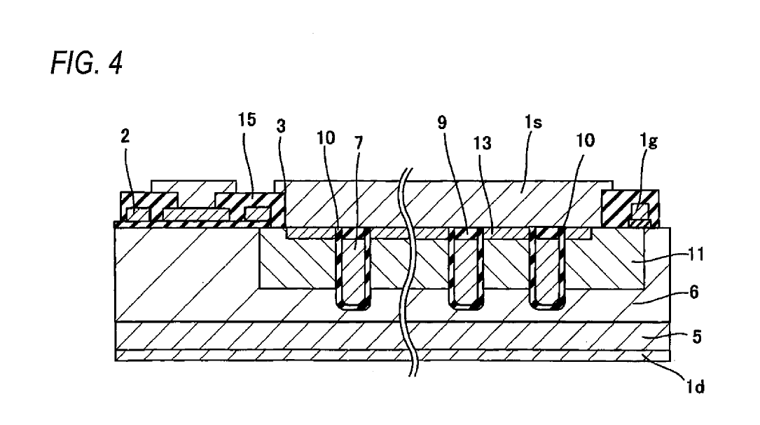

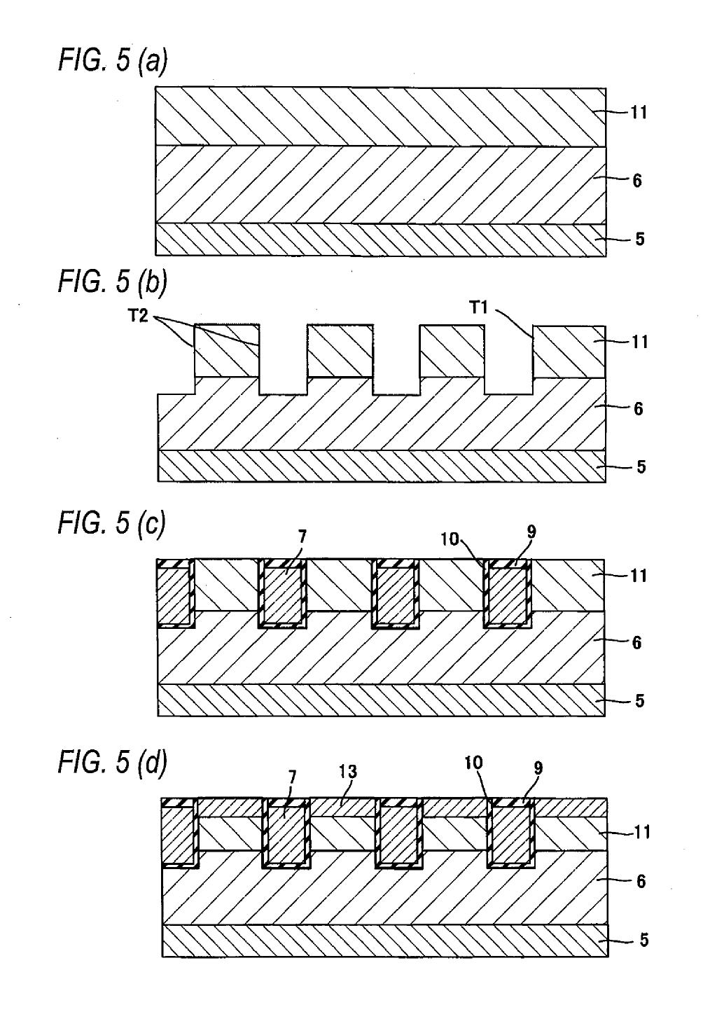

FIG. 1 is an explanatory view showing an edge portion of a trench MOSFET of a first embodiment of the present invention. FIG. 2 is an enlarged view of the principal portion. FIGS. 3 and 4 are overall views of the trench MOSFET. FIG. 3 is a top view, and FIG. 4 is a cross sectional view taken along line A-A shown in FIG. 3. FIGS. 5(a) to (d) are views showing a step for manufacturing the trench MOSFET of the first embodiment. FIGS. 1 and 2 are equivalent to a cross section taken along line B-B shown in FIG. 3.

As shown in FIGS. 1 through 4, the trench MOSFET of the present embodiment is a semiconductor device having a trench gate in an element region formed in a semiconductor substrate. The MOSFET is characterized in that second trenches T2 having the same depth as that of first trenches T1 making up the trench gate are provided along a marginal area of the semiconductor substrate. A width W₁ of each of the first trenches T1 is assumed to be equal to a width W₂ of each of the second trenches T2 in the scribe region 2.

A customary configuration is adopted for the other portion of the MOSFET. As shown in FIGS. 1 through 4, a source region 13 has the first trenches T1 formed in a semiconductor layer. Each of the first trenches T1 is filled with polycrystalline silicon by way of a gate oxide film 10 made of silicon oxide, thereby forming a trench gate 7. The source region 13 is formed to a given depth at both ends of each of the trench gates 7 so as to contact the trench gates 7. The source region 13 is electrically connected to a source electrode 1s (a source pad) at a source contact opening 3.

A drain region is made up of an n⁻-type epitaxial layer 6 and an n⁺-type silicon substrate 5, and an entire back side of a semiconductor chip acts as a drain electrode 1d.

Specifically, the semiconductor chip includes the trench gates 7 formed by embedding a polycrystalline silicon film (a conductor layer) into the plurality of stripe-shaped trenches T1 formed in the n⁻-type epitaxial layer 6 laid over the surface of an n⁺-type silicon substrate 5 by way of the gate oxide film 10; an insulation film 15 formed from a silicon oxide film so as to cover the surface of the semiconductor layer; a source electrode 1s formed on the insulation film 15 so as to contact the source region 13 by way of the source contact opening 3; a gate peripheral line 2 connected to the trench gates 7 in marginal areas of the respective trench gates 7; a gate electrode 1g that exists in the same plane where the source electrode 1s is provided and that is formed at a position spaced apart from the source electrode 1s and connected to the gate peripheral line 2; and a drain electrode 1d formed on the back of the silicon substrate.

As shown in FIGS. 3 and 4, the gate peripheral line 2 is laid between a region where the gate electrode 1g is formed and the source electrode 15 so as to surround the region where the gate electrode 1g is formed, as well as in a marginal area of the chip. Therefore, a power feed line for feeding power to the trench gates is made shorter, so that line resistance can be diminished.

A method for manufacturing the semiconductor device of the present invention is now described by reference to FIG. 5. In relation to a step for forming trenches, the manufacturing method is identical with the related art manufacturing method.

Under a method for manufacturing an n-type MOSFET having a stripe-shaped trench gate structure, as shown in FIG. 5(a) an n⁺-type silicon wafer is used as the silicon substrate 5 that is to form a semiconductor substrate, and the n⁻-type epitaxial layer 6 is formed on a top surface of the silicon substrate 5. A p-type well layer 11 is formed within the n⁻-type epitaxial layer 6.

As shown in FIG. 5(b), the first trenches T1 and the second trenches T2 are formed in the surface of the n⁻-type epitaxial layer 6 including the p-type well layer 11, by means of photolithography and dry etching. The first trenches T1 are formed in the element region, and the second trenches T2 are formed in the scribe region. The trenches are formed as patterns that have the same width and that are oriented in the same direction.

Subsequently, the gate oxide film 10 having a thickness of the order of 30 nm is formed on sidewalls of the respective trenches by thermal oxidation as shown in FIG. 5(c). A polycrystalline silicon film (the trench gate) 7 is deposited in the respective trenches T1 and T2 by means of CVD, and the polycrystalline silicon film (7) is doped with impurities. Unwanted portions are then eliminated by means of chemical mechanical polishing (CMP) or etchback, and a silicon oxide film (an insulation film 9) is formed on the polycrystalline silicon film (7) by means of thermal oxidation.

In order to form an n-type diffused layer that is to become the source region 13 and a p⁺-type diffused layer that is to become the body contact region 12, phosphor and boron impurities are implanted into the p-type well layer 11 by means of ion implantation as shown in FIG. 5(d).

An insulation film 8 and a protective film 14 are deposited on the surface of the semiconductor substrate. The source contact opening 3 is formed in order to make an electrical connection between the source electrode 1s and the source region 13. An aluminum thin film is formed, thereby forming a metallic line making up the source electrode 1s, or the like. There is thus formed a semiconductor wafer having the trenches T1 and T2 of the same depth in element regions R1 and the scribe regions R2, respectively.

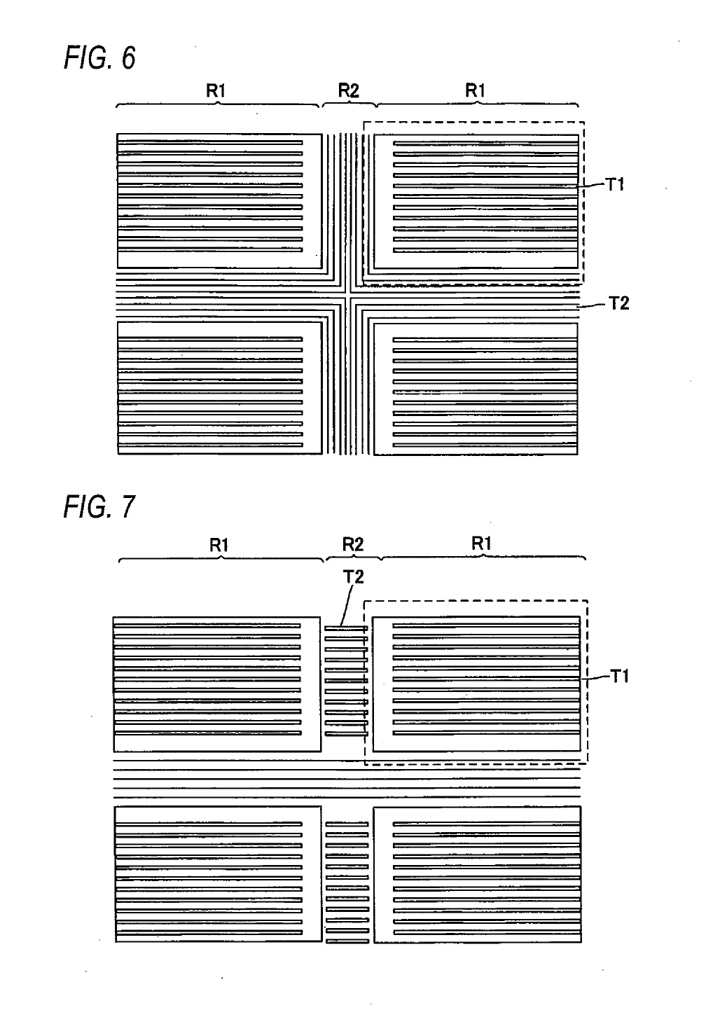

FIG. 6 is a plan view showing a portion of the semiconductor wafer. The semiconductor wafer is separated into the respective element regions R1 by separating the scribe regions R2 by means of a dicing saw, thereby producing a plurality of element chips.

A semiconductor device shown in FIGS. 1 through 4 is thus produced by means of changing only the mask pattern on the occasion of formation of the trenches.

Since the wafer is separated at a position designated by a dicing line D1 shown in FIG. 1 during dicing operation, the second trenches T2 are present along the marginal area of the element chip. By means of presence of the second trenches, it becomes possible to prevent occurrence of a minute deformation, which would otherwise be caused by a difference among a silicon substrate, an electrode, and a material of a line, in terms of a coefficient of linear expansion, during formation of an electrode, a line, and the like.

The wafer is separated at a position designated by a dicing line D2 shown in FIG. 1 as the case may be, to thus prevent the trenches from existing in the marginal area of the element chip. Since occurrence of warpage can be prevented at the wafer level even in this case, the invention is effective.

In the embodiment, as shown in FIG. 6, the second trenches T2 are formed in the scribe regions R2 in the same step during which the first trenches T1 are formed, so as to become identical, in terms of a width and a depth, with the first trenches T1 that are formed in the element region R1, to thus make up the trench gates, thereby making it possible to form a high-precision pattern while preventing occurrence of warpage in a semiconductor wafer. A broken line shows one chip unit.

Since the second trenches T2 are shallow, deterioration of mechanical strength does not occur, and strength can be maintained well. Moreover, since the second trenches are formed in the scribe regions R2 simultaneously in the step of forming trench gates, manufacturing cost becomes low. Further, trenches are formed over the entire wafer, and hence it is possible to make the geometry of the trenches stable in the trench etching step. Even semiconductor devices (element chips) produced from the semiconductor wafer are consequently subjected to lessening unevenness in electrical characteristic, so that yield of the semiconductor devices can be enhanced.

Since the semiconductor wafer is free of warpage, higher precision can be achieved even in other steps, such as formation of an electrode pattern.

Moreover, since the plurality of second trenches T2 are formed in the scribe regions R2 so as to surround the element regions R1, stress is released. Since the element regions R1 become independent on a per-region basis, further lessening of warpage becomes feasible. Even when the semiconductor wafer is heated in the ion implantation step, or the like, the surface of the semiconductor wafer becomes thermally isolated. Therefore, reliability of the semiconductor wafer can be enhanced.

### Second Embodiment

A second embodiment of the present invention is now described.

In the second embodiment, the direction of the second trenches T2 in the scribe regions R2 of the first embodiment is changed as shown in FIG. 7, and the second trenches T2 are formed so as to become parallel to the first trenches T1. Even in this case, the first trenches T1 and the second trenches T2 are simultaneously formed.

By means of the configuration, since all of the first trenches T1 and the second trenches T2 run in the same direction, stable patterning becomes possible. A broken line designates one chip unit.

### Third Embodiment

A third embodiment of the present invention is now described.

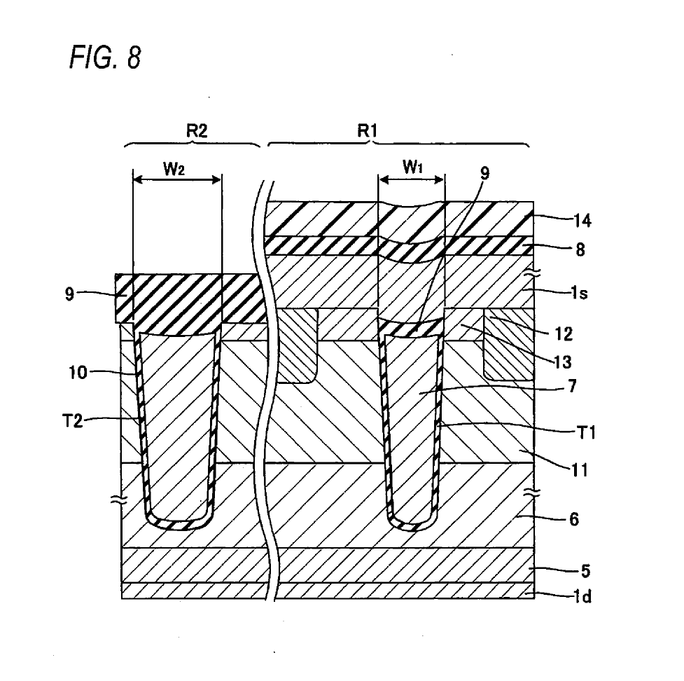

In the third embodiment, as shown in FIG. 8, the second trenches T2 are formed in the scribe regions R2 so as to assume the width W₂ that is greater than the width W₁ of the first trenches T1. The semiconductor device is analogous to that described in connection with the preceding embodiments in terms of the other configuration.

The configuration makes formation of a mask pattern easy and enables performance of stable patterning operation.

In the embodiment, the second trenches T2 are filled with polycrystalline silicon, but the trenches T2 may also be filled with an insulating material, like polyimide.

The present embodiment has provided descriptions about the trench MOSFET. However, the present embodiment is not limited to the MOSFET but also applicable to another element having a trench structure, such as an insulated gate bipolar transistor (IGBT), a trench capacitor, and DRAM.

### INDUSTRIAL APPLICABILITY

As has been described, the present invention makes it possible to provide a highly-reliable semiconductor device that lessens warpage and that exhibits high mechanical strength. Hence, the present invention is effective for application to an electronic device having a minute structure.

### DESCRIPTIONS OF THE REFERENCE NUMERALS AND SYMBOLS

1g GATE ELECTRODE
1s SOURCE ELECTRODE
1d DRAIN ELECTRODE
2 GATE PERIPHERAL LINE
3 SOURCE CONTACT OPENING
T1 FIRST TRENCH
T2 SECOND TRENCH
5 N⁺-TYPE SILICON SUBSTRATE
6 N⁻-TYPE SILICON EPITAXIAL LAYER
7 TRENCH GATE (POLYCRYSTALLINE SILICON)
8, 9 INSULATION FILM
10 GATE OXIDE FILM
11 P-TYPE WELL LAYER (BODY REGION)
12 BODY CONTACT REGION
13 SOURCE REGION
14 PROTECTIVE FILM
R1 ELEMENT REGION
R2 SCRIBE REGION

1. A semiconductor device, having:
trench gates in an element region formed in a semiconductor substrate, wherein second trenches having the same depth as that of first trenches making up the trench gates are formed in a marginal area of the semiconductor substrate.

2. The semiconductor device according to claim 1, wherein a polycrystalline silicon film is formed on interior walls of the respective second trenches by an oxide film.

3. The semiconductor device according to claim 1, wherein the semiconductor substrate is formed from a semiconductor base material and an epitaxial growth layer formed on a surface of the semiconductor base material; and wherein the first trenches and the second trenches have such a depth that they do not reach an interface between the semiconductor base material and the epitaxial growth layer.

4. The semiconductor device according to claim 1, wherein the second trenches are formed in parallel to the first trenches.

5. The semiconductor device according to claim 1, wherein the second trenches are parallel to edges of the respective element regions and formed so as to surround the respective element regions.

6. The semiconductor device according to claim 1, wherein the second trenches have the same width as that of the first trenches.

7. A method for manufacturing a semiconductor device, comprising:
preparing a semiconductor substrate;
forming first trenches in element regions of the semiconductor substrate and second trenches in scribe regions surrounding the respective element regions;
oxidizing interior walls of the first and second trenches, to thus produce a silicon oxide film, and filling interiors of the trenches with polycrystalline silicon, to form gate electrodes in the first trenches;
forming trench gate semiconductor devices through introduction of impurities and formation of electrodes;
and
separating the substrate into a plurality of semiconductor devices by bringing a dicing blade into contact with the scribe regions.

8. The method for manufacturing a semiconductor device according to claim 7, wherein a silicon oxide film is formed on respective interior walls of the first trenches, and the first trenches are filled with polycrystalline silicon, to thus form the gate electrodes; and simultaneously a silicon oxide film is also formed on respective interior walls of the second trenches, and the second trenches are filled with polycrystalline silicon.

9. The method for manufacturing a semiconductor device according to claim 7, wherein the step of preparing the semiconductor substrate includes the steps of:
forming an epitaxial growth layer on a surface of a semiconductor base material; and
forming the first and second trenches to such a depth that they do not reach an interface between the semiconductor base material and the epitaxial growth layer.

10. The method for manufacturing a semiconductor device according to claim 7, wherein the step of forming trenches includes the step of simultaneously forming the first and second trenches in such a way that the second trenches become parallel to the first trenches.

11. The method for manufacturing a semiconductor device according to claim 7, wherein the step of forming trenches includes a step of simultaneously forming the first and second trenches in such a way that the second trenches become parallel to edges of the element regions so as to surround the respective element regions.

12. The method for manufacturing a semiconductor device according to claim 7, wherein the second trenches are formed in numbers at a predetermined pitch within the respective scribe regions so as to have the same width as that of the first trenches.
